(19) United States
(12) Patent Application Publication
(10) Pub. No.: US 2014/0318608 A1
(43) Pub. Date: Oct. 30, 2014

(54) SOLAR CELL MANUFACTURING METHOD AND SOLAR CELL

(71) Applicant: ULVAC, INC., Chigasaki-shi (JP)

(72) Inventors: Genji Sakata, Chigasaki-shi (JP); Hidekazu Yokoo, Chigasaki-shi (JP); Makoto Tomita, Chigasaki-shi (JP); Hideo Suzuki, Chigasaki-shi (JP)

(21) Appl. No.: 14/360,732

(22) PCT Filed: Oct. 11, 2012
(86) PCT No.: PCT/JP2012/076322

§ 371 Date: May 27, 2014

(30) Foreign Application Priority Data
Nov. 29, 2011 (JP) 2011-260064

(51) Int. Cl. H01L 21/66; H01L 31/0224; H01L 31/18

(52) U.S. Cl. CPC H01L 22/20; H01L 31/18; H01L 31/022425
USPC 136/252; 438/7

(57) ABSTRACT

A method of manufacturing a solar cell includes a first center alignment step S10 of setting a substrate center position as a reference position for processing of an impurity implanting step S20 and a second center alignment step S30 of setting a substrate center position as a reference position for processing of an electrode forming step S40.

### CROSS-REFERENCE TO RELATED APPLICATION

This is the U.S. National Phase Application under 35 U.S.C. §371 of International Patent Application No. PCT/JP2012/076322 filed Oct. 11, 2012, which designated the United States and was published in a language other than English, which claims the benefit of Japanese Patent Application No. 2011-260064 filed on Nov. 29, 2011, both of which are incorporated by reference herein.

### TECHNICAL FIELD

The present invention relates to a technique suitable for use in a solar cell manufacturing method and a solar cell.

### BACKGROUND

Conventionally, techniques of forming a pn junction in a monocrystalline silicon substrate or a polycrystalline silicon substrate by introducing impurities such as phosphorus or arsenic and forming a solar cell are known. In such a solar cell, it is generally known that conversion efficiency (power generation efficiency) decreases when electrons and holes formed in the pn junction are recombined. Accordingly, a selective emitter structure has been proposed in which a concentration of impurities to be introduced into a part to be in contact with a front electrode is higher than that of the other part at the time of introduction of impurities so as to locally set resistance of an emitter layer in a part not having an electrode formed thereon to be higher. An impurity-implanted region (ion-irradiated region) may be set with a mask by using an ion implantation method used to manufacture a semiconductor device for introduction of impurities in the selective emitter structure.

The front electrode is formed to form the selective emitter structure, but in order to not decrease conversion efficiency, the front electrode is formed in an impurity region subjected to the ion implantation.

Therefore, alignment for positioning the substrate is required for the processes and a technique of positioning the substrate using at least two sides of the substrate is known.

A substrate might be positioned by touching the edges of the substrate (Patent Document 1).

### RELATED ART DOCUMENTS

### Patent Documents

[Patent Document 1] Published Japanese Translation No. 2010-539684 of the PCT International Publication

### SUMMARY OF INVENTION

### Problems to be Solved by the Invention

However, unlike a semiconductor substrate, a substrate for manufacturing a solar cell has external form specifications of a rectangle in which one side is about 156 mm but actually has a large margin of error of about ±500 μm in most cases.

The angle of two neighboring sides of the substantially rectangular substrate should be a right angle but is not exactly 90° and has a large tolerance of ±0.3°.

Accordingly, in steps of forming an impurity-implanted region (ion-implanted region) and a front electrode, there is a possibility that an error of about 1000 μm which is 500 μm doubled, or a larger error will occur. In order for the front electrode not to protrude from the ion-implanted region, the front electrode is formed to be much smaller than the ion-implanted region or the ion-implanted region is formed to be much larger than the front electrode. In this case, there is a problem in that conversion efficiency decreases because the electrode is excessively narrowed, an unnecessary ion-implanted region increases, or the like.

In order to solve this problem, it may be considered that two or more alignment marks are formed on the substrate and two steps of the ion implanting step and the front electrode forming step are performed on the basis of the alignment marks. Accordingly, the alignment can be performed with accuracy of 50 μm or less, but there is a problem in that the step of forming the alignment marks is added and an increase in manufacturing cost which should be most strongly avoided is caused as a result.

There is a substrate having an external form specification with a side of about 125 mm in addition to a side of 156 mm. In this case, when the alignment is performed on the basis of the edges of the substrate, there is a problem in that it is not possible to cope with substrates having different processing positions. There is a need for performing the same process on these substrates having different specifications.

Aspects of the present invention are for achieving the following objects:

1. to improve accuracy of alignment in multiple steps while avoiding an increase in manufacturing costs;

2. to maintain accuracy of alignment even in a solar cell substrate having large variation in dimensions of an external (outline) form and to enable processing in multiple steps;

3. to prevent a decrease in conversion efficiency due to formation of an impurity region and a front electrode; and

4. to cope with substrates having different dimensional specifications.

### Means for Solving the Problem

According to an aspect of the present invention, there is provided a method of manufacturing a solar cell having an impurity region formed in a substantially-rectangular silicon substrate and an electrode formed to overlap with the impurity region, the method including: an impurity implanting step of forming the impurity region; an electrode forming step of forming the electrode; a first center alignment step of setting a center position of the substrate as a reference position for processing the impurity implanting step; and a second center alignment step of setting a center position of the substrate as a reference position for processing the electrode forming step.

The first center alignment step may include calculating a substrate center position from an image acquired by imaging an external form of the substrate with an imaging unit located on the opposite side of a processing surface of the substrate.

The second center alignment step may employ calculating a substrate center position from an image acquired by imaging an external form of the substrate with an imaging unit located on the side of a processing surface of the substrate.

The impurity implanting step may include implanting impurities using an ion implantation method.

It is preferable that the electrode forming step include forming the electrode using a printing method.

The first or second center alignment step may include calculating a vertex by extending predetermined parts of two neighboring sides of the external form of the substrate, similarly calculating a vertex at a diagonal position thereof, and setting a midpoint of a diagonal line which is a straight line connecting the two vertexes as the substrate center position.

The first or second center alignment step may include calculating a vertex by extending predetermined parts of two neighboring sides of the external form of the substrate, similarly calculating a vertex neighboring the vertex, determining a midpoint of a line connecting the two neighboring vertexes, calculating midpoints of opposite sides from the other two vertexes so as to correspond to the midpoint, similarly calculating midpoints of the other two opposite sides, and setting an intersection of straight lines connecting two points which are the midpoints of the two opposite sides as the substrate center position.

The first or second center alignment step may include considering that an intersection angle of two neighboring sides of the external form of the substrate and the diagonal line is 45°.

It is preferable that the first center alignment step include imaging the external form of the substrate via an imaging hole penetrating a support pedestal on which the substrate is placed.

A solar cell according to another aspect of the present invention may be manufactured using any method described above.

The method of manufacturing a solar cell according to the aspect of the present invention is a method of manufacturing a solar cell having an impurity region formed in a substantially-rectangular substrate and an electrode formed to overlap with the impurity region, the method including: the impurity implanting step of forming the impurity region; the electrode forming step of forming the electrode; the first center alignment step of setting a center position of the substrate as a reference position for processing of the impurity implanting step; and the second center alignment step of setting the center position of the substrate as a reference position for processing of the electrode forming step.

According to this configuration, it is possible to accurately control the formation positions of the impurity region and the electrode between the impurity implanting step and the electrode forming step. Accordingly, even when the external form of the substrate has an error, it is possible to form the electrode so as not to protrude from the impurity region without being affected by the error.

Accordingly, it is possible to accurately form the electrode having substantially the same width with respect to the impurity region having a width of about 50 to 500 μm. Accordingly, it is possible to manufacture solar cells using substrates having different dimensional specifications with the same apparatus without causing a decrease in conversion efficiency.

In the first center alignment step for the impurity implanting step, the substrate center position is calculated from an image acquired by imaging the external form of the substrate with the imaging unit located on the opposite side of the processing surface of the substrate. Accordingly, the substrate surface on the implantation side in the vicinity of a mask used for impurity implantation can be imaged by the imaging unit (such as a CCD or a digital camera) located on the opposite side of the substrate. As a result, it is possible to perform a precise impurity implantation process on the entire surface of the substrate and to accurately determine the processing position by setting the substrate center position.

In the second center alignment step for the electrode forming step, the substrate center position is calculated from an image acquired by imaging an external form of the substrate with the imaging unit located on the side of the processing surface of the substrate. Accordingly, after the substrate center position is calculated, the substrate can be made to move by a predetermined amount (distance, direction, angle, or the like) in a direction parallel to a mask, that is, parallel to the substrate surface, relative to the mask (screen) or the like used to form an electrode. As a result, it is possible to accurately determine the formation position of the electrode and to accurately form the electrode with substantially the same width as the impurity region having a width of about 50 to 500 μm, strictly, with a width smaller by about 10 μm than the width of the impurity region.

In the impurity implanting step, impurities are implanted using an ion implantation method. Specifically, ions of the impurities are introduced by irradiation with the ions of the impurities from an ion gun, the ion gun is installed so that an ion irradiation surface thereof faces the substrate placed at the processing position, and the ion irradiation is performed using the substrate center position as a reference position. At this time, by employing a configuration in which the ions of impurities are applied from a direction substantially perpendicular to the substrate, it is possible to introduce the ions of impurities up to any depth position from the substrate surface by a channeling phenomenon. Accordingly, compared with a case where a coating and diffusing method is used, the number of steps is smaller and the annealing time for thermally diffusing the impurities introduced into the substrate is shorter, thereby improving mass productivity. A mass separator, an accelerator, or the like is not necessary for introducing the ions of impurities, thereby achieving a decrease in cost.

When a direction from the ion irradiation surface to the substrate is defined as a downward direction, it is preferable that the ion gun include a plasma generation chamber which can generate plasma including ions of impurities and a grid plate which is installed at the lower end of the plasma generation chamber to form the ion irradiation surface and that the ion guns have a configuration in which multiple through-holes are formed in the grid plate, an area having the through-holes formed therein is larger than the area of the substrate, and the grid plate is maintained at a predetermined voltage to guide down the ions of impurities in the plasma generated in the plasma generating chamber via the through-holes.

According to this configuration, it is possible to control the depth or concentration of impurities in the substrate with high accuracy by only controlling the voltage to be applied to the grid plate. In addition, since the area of the grid plate having the through-holes formed therein is larger than the area of the substrate and the entire surface of the substrate is evenly irradiated with the ions of impurities, it is possible to shorten the processing time in comparison with a case where the substrate surface is scanned with an ion beam, thereby achieving a further decrease in cost.

In another aspect of the present invention, it is preferable to include a mask that is disposed between the ion irradiation surface and the substrate to locally shield the substrate and a movement unit for moving the position of the substrate to be forward and backward movable to an arbitrary position and rotatable relative to the mask and the ion irradiation surface. According to this configuration, it is possible to locally introduce ions of impurities into the substrate by only appropriately moving the substrate relative to the mask, which is particularly advantageous for introduction of impurities in the selective emitter structure. Accordingly, the steps of forming a mask on the surface of the substrate, removing the mask, or the like are made to be unnecessary, thereby further improving mass productivity.

In another aspect of the present invention, the solar cell manufacturing method may include an ion irradiation step of irradiating a solar cell substrate with ions of impurities selected from P, As, Sb, Bi, B, Al, Ga, and In from the ion irradiation surface of the ion gun disposed to face the substrate, a defect repairing step of repairing defects formed in the substrate in the ion irradiation step through the use of an annealing process, and an impurity diffusing step of diffusing the impurities through the use of the annealing process. Here, the above-described substrate includes a substrate having a texture structure on the surface irradiated with the ions of impurities.

According to the aspect of the present invention, since the ions of impurities are introduced up to an arbitrary depth position from the substrate surface by the channeling phenomenon, it is possible to implant the ions of impurities with lower energy. Accordingly, the annealing time for repairing defects (that is, recrystallization) is shortened and the annealing time for diffusing the impurities is shortened, thereby improving mass productivity of a solar cell.

In the electrode forming step, the electrode is formed using a printing method. Accordingly, it is possible to form the electrode using a low-cost method such as screen printing and inkjet printing. Regarding the printing position, it is possible to set the substrate center position at the time of performing a printing process by setting the substrate center position at a position spaced apart in the direction parallel to the substrate surface and setting the printing position to a position shifted by a predetermined distance and/or a predetermined angle.

Therefore, in multiple steps of impurity implantation (ion implantation) and electrode formation (screen printing) which are performed by different processing units (processing apparatuses), it is possible to accurately align the substrate by setting the substrate center positions and to guarantee accuracy of the processing position.

In the first or second center alignment step, a vertex is calculated by extending predetermined parts of two neighboring sides of the external form of the silicon substrate, a vertex at a diagonal position thereof is similarly calculated, and a midpoint of a diagonal line which is a straight line connecting the two vertexes is set as the substrate center position. Accordingly, even with a substrate having four corners chipped and not having a corner, it is possible to set the center position by calculating the vertexes thereof and to enable alignment based on the substrate center position.

In the first or second center alignment step, it is considered that an intersection angle of two neighboring sides of the external form of the silicon substrate and the diagonal line is 45°. Accordingly, even when the external form of a substrate is not exactly rectangular (rectangular or square), that is, even when the external form of a substrate is a quadrangle having a shape in which four sides of a rectangle are curved, it is possible to accurately set the rotational position about the substrate center position.

In the first or second center alignment step, a vertex is calculated by extending predetermined parts of two neighboring sides of the external form of the silicon substrate, a vertex neighboring the vertex is similarly calculated, a midpoint of a line connecting the two neighboring vertexes is determined, midpoints of opposite sides are calculated from the other two vertexes so as to correspond to the midpoint, midpoints of the other two opposite sides are similarly calculated, and an intersection of straight lines connecting two points as the midpoints of the two opposite sides is set as the substrate center position. Accordingly, it is possible to enable alignment of a trapezoidal substrate. In this case, an angle formed by the straight line connecting the two neighboring vertexes and two neighboring sides of the external form of the silicon substrate can be considered to be 0°. Accordingly, even when the external form of a substrate is not exactly rectangular (rectangular or square), that is, even when the external form of a substrate is a quadrangle having a shape in which four sides of a rectangle are curved, it is possible to accurately set the rotational position about the substrate center position.

In the first center alignment step for the impurity implanting step, since the external form of the substrate is imaged via an imaging hole penetrating a support pedestal on which the substrate is placed, it is possible to set the center of even a substrate placed on the support pedestal by the use of an imaging apparatus disposed on the opposite side of the processing surface. Accordingly, at the processing position, which is close to the mask, for performing an implantation process, it is possible to check the substrate center position and the rotational position about the center of the substrate and to accurately set the position of the substrate.

By manufacturing a solar cell according to an aspect of the present invention using any method described above, it is possible to manufacture a solar cell with high conversion efficiency without causing an increase in manufacturing cost.

### Advantage of the Invention

According to the aspects of the present invention, it is possible to improve accuracy of alignment in multiple steps while avoiding an increase in manufacturing costs;

According to the aspects of the present invention, it is possible to maintain accuracy of alignment even in a solar cell substrate having large variation in dimensions of an external form and to enable processing in multiple steps;

According to the aspects of the present invention, it is possible to prevent a decrease in conversion efficiency due to formation of an impurity region and a front electrode; and

According to the aspects of the present invention, it is possible to cope with substrates having different dimensional specifications.

### BRIEF DESCRIPTION OF THE DRAWINGS

FIG. 1 is a plan view illustrating a substrate and a method of calculating a substrate center position in a solar cell manufacturing method according to an embodiment.

FIG. 2 is a flowchart illustrating steps in the solar cell manufacturing method according to the embodiment.

FIG. 3 is a cross-sectional view schematically illustrating an ion implantation apparatus used in the solar cell manufacturing method according to the embodiment.

FIG. 4 is a plan view illustrating a support pedestal in FIG. 3.

FIG. 5A is a cross-sectional view schematically illustrating a step in the solar cell manufacturing method according to the embodiment.

FIG. 5B is a cross-sectional view schematically illustrating a step in the solar cell manufacturing method according to the embodiment.

FIG. 5C is a cross-sectional view schematically illustrating a step in the solar cell manufacturing method according to the embodiment.

FIG. 6 is a cross-sectional view schematically illustrating a screen printing apparatus used in the solar cell manufacturing method according to the embodiment.

FIG. 7 is a cross-sectional view schematically illustrating an example of a solar cell manufactured using the solar cell manufacturing method according to the embodiment.

FIG. 8 is a cross-sectional view schematically illustrating another example of a solar cell manufactured using the solar cell manufacturing method according to the embodiment.

FIG. 9 is a plan view illustrating another example of the substrate and the method of calculating a substrate center position.

### DESCRIPTION OF THE EMBODIMENTS

Hereinafter, a solar cell manufacturing method according to an embodiment of the present invention will be described with reference to accompanying drawings.

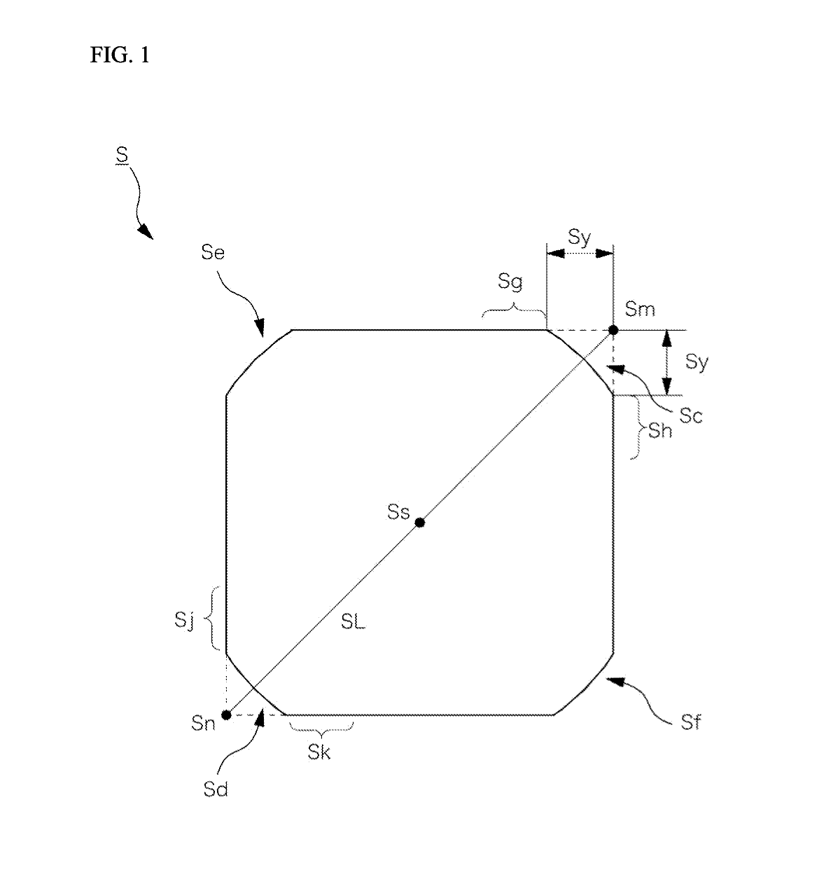

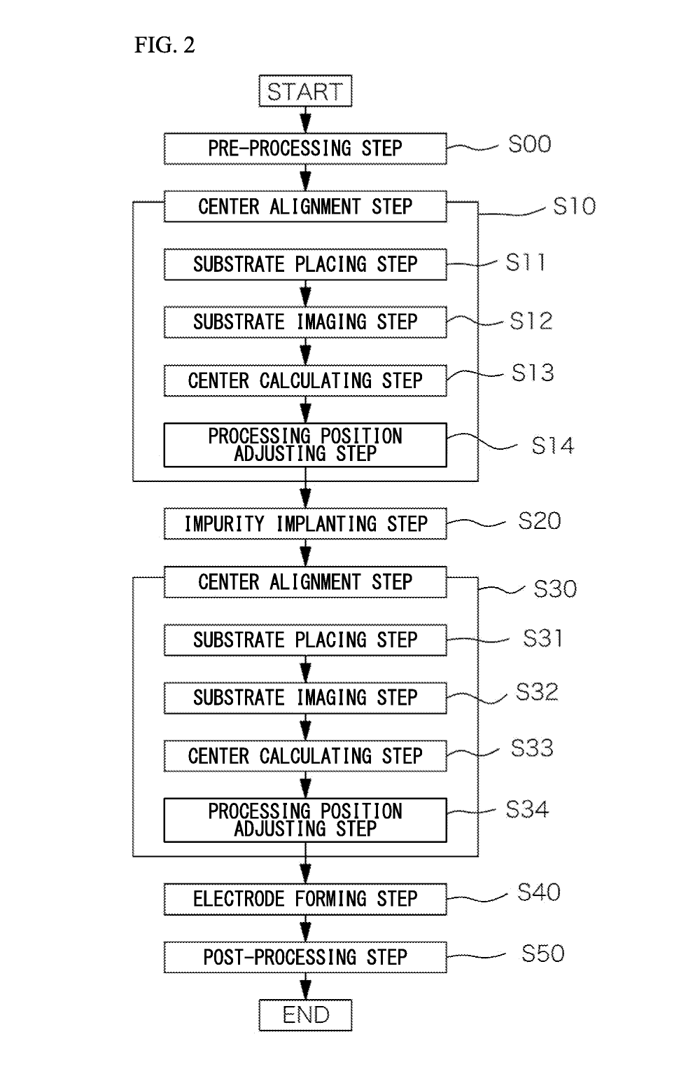

FIG. 1 is a plan view illustrating a solar cell substrate in this embodiment and FIG. 2 is a flowchart illustrating steps in this embodiment.

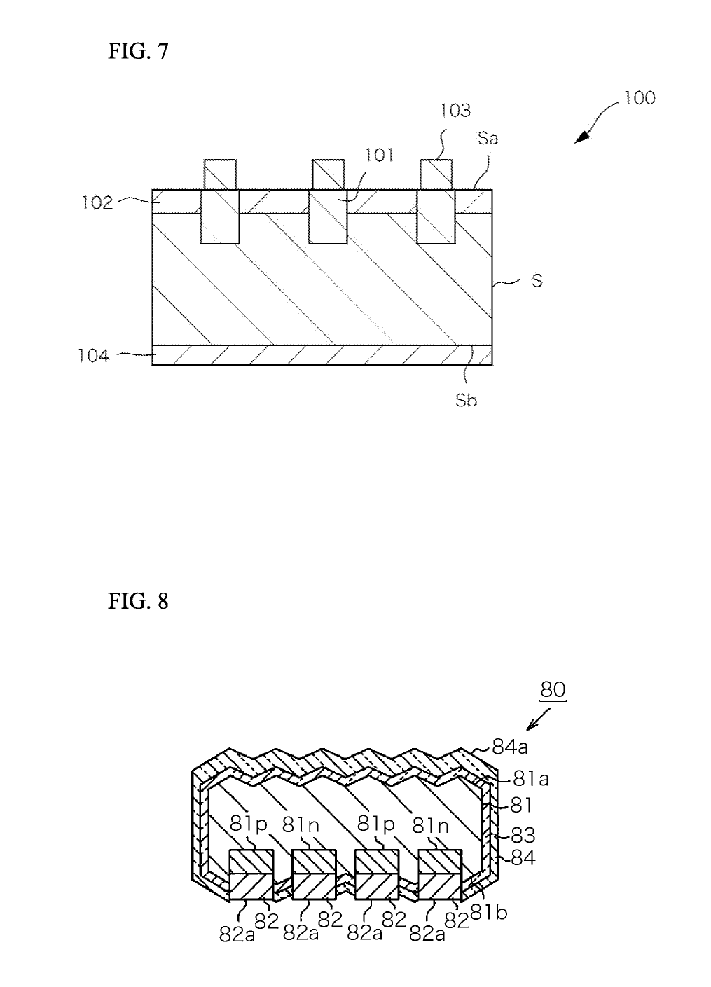

In the solar cell manufacturing method according to this embodiment, as illustrated in FIGS. 1 and 7, a monocrystalline or polycrystalline silicon substrate having an external form of which four corners are chipped and in which the length Sy of a part having a corner chipped is about 20 mm is used as a substrate S. A solar cell having a selective emitter structure can be manufactured by introducing phosphorus or boron into the substrate.

In FIG. 7, for the purpose of convenience of explanation of the entire structure of a solar cell, an uneven texture formed on the outer surface of the solar cell and a film covering side surfaces other than a light-receiving surface of the solar cell and a rear surface opposite thereto are not illustrated. A solar cell 100 is a solar cell having a selective emitter structure. As illustrated in FIG. 7, impurity regions 101 which are regions in which impurity elements are diffused are formed by a predetermined depth in the thickness direction of the substrate S on a front surface Sa as a solar-light-receiving surface in a silicon substrate S having a rectangular plate shape as a semiconductor substrate, front electrodes (electrode) 103 connected to an outside are formed on the impurity regions 101, and a rear electrode 104 connected to an outside is formed on the entire area of a rear surface Sb.

Each impurity region 101 is formed in a stripe shape, has, for example, an n type, and may include elements such as phosphorus (P) and arsenic (As) which are a second conductivity type of impurity elements. At least the rear surface side of the substrate S in contact with the rear electrode 104 has an impurity region, and this impurity region may include elements such as boron (B), antimony (Sb), and bismuth (Bi) which are a first conductivity type of impurity elements.

In the impurity region 101, an electrode (finger electrode) 103 formed of aluminum, silver, or the like is formed to protrude from the front surface Sa of the silicon substrate S. Light incident on the light-receiving surface Sa of the silicon substrate S is converted into electric power in the impurity region 101 and the rear surface side of the substrate S.

This electric power is extracted from the front electrodes 103 connected to the impurity regions 101 and the rear electrode 104 to an external load or a power storage device.

The entire surface of the silicon substrate S is covered with a silicon oxide film and a silicon nitride film covering the silicon oxide film so as to expose at least the top surface of the electrodes 103 and a part of the surface of the rear electrode 104. The light-receiving surface Sa side of the silicon nitride film serves as a reflection suppressing portion suppressing reflection of light. Light applied to the front surface of the solar cell 100 easily enters the silicon substrate S by the reflection suppressing function of the reflection suppressing portion. The light entering the silicon substrate S is easily trapped by the texture formed on the light-receiving surface Sa. Light entering the silicon substrate S or light trapped by the silicon substrate is converted into electric power through a photoelectric conversion operation in the impurity regions 101 and on the rear surface side of the substrate which is an impurity region. A passivation film that suppresses intrusion of impurities such as moisture into the silicon substrate S, mechanical damage on the outer surface of the silicon substrate S, and the like is formed by the silicon oxide film and the silicon nitride film including the reflection suppressing portion.

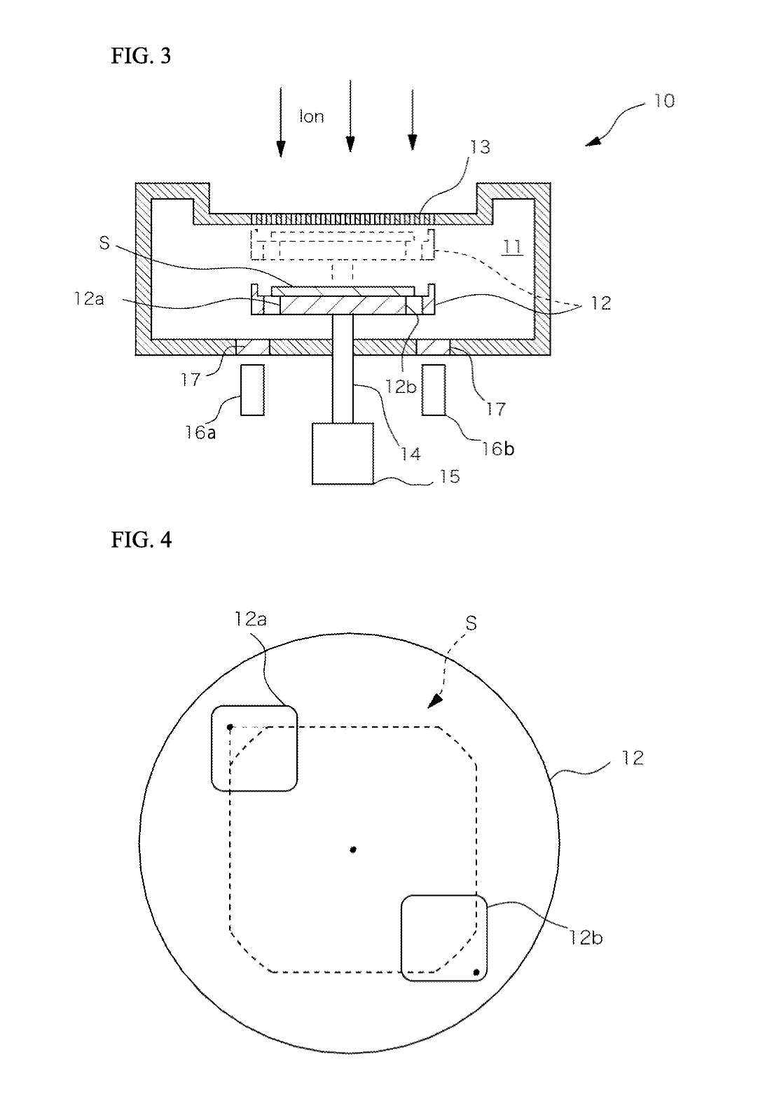

In the solar cell manufacturing method according to this embodiment, in an impurity implanting step S20 to be described later, an impurity implanting process is performed using an ion implantation apparatus 10 illustrated in FIGS. 3 and 4.

As illustrated in FIG. 3, the ion implantation apparatus 10 includes a support pedestal 12 on which a processing substrate S is placed in a processing chamber 11, an ion irradiation unit for irradiating the substrate S placed on the support pedestal 12 with ions from an ion source not illustrated, a mask 13 defining an irradiation area of the substrate S which is irradiated with the ions, a support pedestal positioning unit 15 for moving the support pedestal 12 in the X, Y, and Z directions and rotating the support pedestal about a support shaft 14 supporting the support pedestal 12 by an arbitrary angle θ, multiple digital cameras (imaging device) 16a and 16b which are disposed on the opposite side of the mask 13 with the support pedestal 12 interposed therebetween, and a window section 17 that is disposed to allow the digital cameras 16a and 16B to image the inside of the processing chamber.

The support pedestal 12 is provided with at least two imaging holes 12a and 12b penetrating the bottom thereof having the substrate S placed thereon, as illustrated in FIGS. 3 and 4.

The imaging holes 12a and 12b are installed in parts corresponding to the surroundings of the corner portions Sc and Sd located at diagonal positions of the substrate S and are located to image the external forms (outlines) of the corner portions of the silicon substrate S via the imaging holes 12a and 12b penetrating the support pedestal 12 as will be described later when the substrate S is located in the vicinity of the mask 13 in a state where the substrate can be subjected to an ion implanting process. The imaging holes 12a and 12b are set to such a size capable of imaging all identified sides Sg, Sh, Sj, and Sk.

The support pedestal 12 is supported by the support shaft 14 at the center thereof, and the support shaft 14 is driven by the support pedestal positioning unit 15 capable of moving the support pedestal 12 in the X, Y, and Z directions and rotating the support pedestal by an angle θ.

The mask 13 employs a mask in which a shielding film 13b formed of alumina or the like is formed on a silicon plate 13a to have a predetermined thickness by sputtering or the like, line-like apertures 13c are formed at predetermined intervals in the shielding film 13b by etching or the like depending on the selective emitter structure, and through-holes 13d communicating with the apertures 13c are formed in the plate 13a. The mask 13 is fixed to an upper partition wall forming the processing chamber 11. At the time of irradiation with ions, the position of the support pedestal 12 relative to the mask 13 is adjusted by the support pedestal positioning unit 15.

The digital cameras (imaging unit) 16a and 16b such as CCD cameras image the substrate S via the imaging holes 12a and 12b and the window sections 17, and are installed outside the processing chamber so as to fix the positions thereof to the processing chamber 11 to correspond to the imaging holes 12a and 12b, respectively.

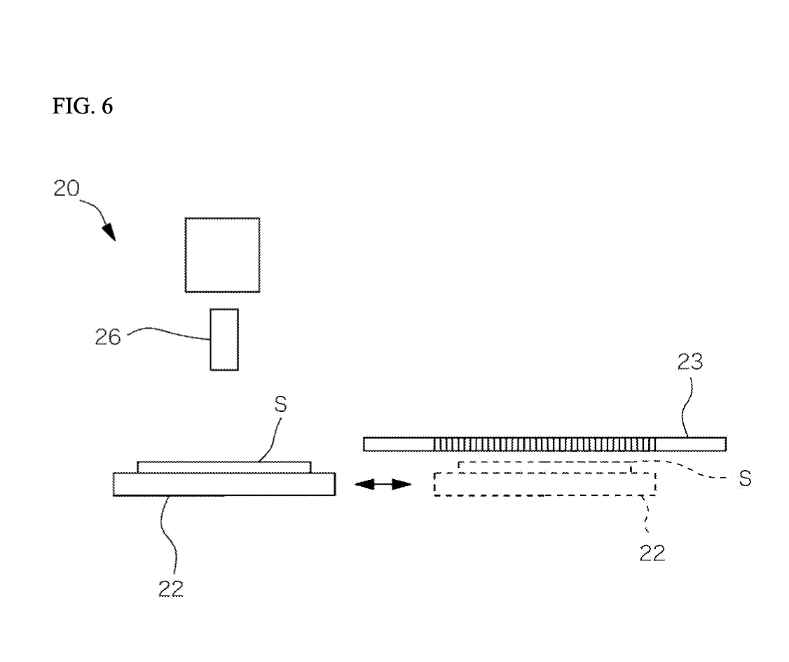

In the solar cell manufacturing method according to this embodiment, in an electrode forming step S40 to be described later, an electrode forming process of forming the front electrodes 103 out of Ag using a known screen printing method is performed by the use of a screen printing apparatus 20 illustrated in FIG. 6.

As illustrated in FIG. 6, the screen printing apparatus 20 includes a screen 23, a support pedestal 22 that is movable relative to the screen 23 between a printing position (dotted line) for performing a printing process and an alignment position (solid line), and a digital camera (imaging unit) 26 such as a CCD camera. The screen printing apparatus 20 includes support pedestal driving unit for moving the support pedestal 22 on which the substrate S is placed between the printing position (dotted line) and the alignment position (solid line) and adjusting the position of the support pedestal 22 in the in-plane direction of the substrate and in an angle direction on the basis of information imaged with the digital camera 26 at the alignment position.

The digital camera (imaging unit) 26 is located on the same side as the screen 23 with respect to the support pedestal 22.

In this embodiment, as illustrated in FIG. 2, the solar cell manufacturing method includes a pre-processing step S00, a substrate placing step S11, a substrate imaging step S12, a center calculating step S13, a processing position adjusting step S14, and an impurity implanting step S20 as a (first) center alignment step S10, a substrate placing step S31, a substrate imaging step S32, a center calculating step S33, a processing position adjusting step S34, and an electrode forming step S40 as a (second) center alignment step S30, and a post-processing step S50. The processes performed in the steps will be described below in detail.

The pre-processing step S00 illustrated in FIG. 2 includes all the steps necessary before implanting impurities, for example, surface treatment such as washing of a substrate, forming of an antireflection film, forming of a texture, and forming of a passivation film.

Specifically, the light-receiving surface Sa and the rear surface Sb of the silicon substrate S are separately immersed in an etching solution for wet etching such as an aqueous solution of potassium hydroxide (KOH). Accordingly, an uneven texture is formed on the light-receiving surface Sa and the rear surface Sb of the silicon substrate S. Subsequently, the silicon substrate S is heated in an oxygen atmosphere in an annealing furnace. A silicon oxide film with a thickness of about 10 nm is formed to cover the entire outer surface of the silicon substrate S by heating in the oxygen atmosphere. The silicon substrate S having the silicon oxide film formed thereon is heated in a nitrogen atmosphere in an annealing furnace. Accordingly, a silicon nitride film with a thickness of about 20 nm is formed to cover the entire outer surface of the silicon oxide film.

Subsequently, the light-receiving surface Sa side of the silicon substrate S is exposed to plasma capable of forming a silicon nitride film. Accordingly, silicon nitride is stacked on only the light-receiving surface Sa side of the silicon substrate S out of the silicon nitride film so as to form the reflection suppressing portion. The thickness of the silicon nitride in the reflection suppressing portion is a thickness for suppressing reflection of solar light input from the outside on the surface of the silicon nitride and ranges from 70 to 80 nm

The center alignment step S10 illustrated in FIG. 2 is a step of setting a substrate center position Sc as a reference position for processing of the impurity implanting step S20 and includes the substrate placing step S11, the substrate imaging step S12, the center calculating step S13, and the processing position adjusting step S14.

In the substrate placing step S11 illustrated in FIG. 2, the substrate S is placed on the support pedestal 12 of the ion implantation apparatus 10. At this time, in order to calculate the substrate center position Ss, substrate corner portions Sc and Sd located at the diagonal positions are positioned to positions at which the substrate corner portions can be imaged with the digital cameras 16 via the imaging holes 12a and 12b from the lower side and then the substrate S is placed. Specifically, as illustrated in FIG. 4, the substrate can be placed so that the corner portion Sc is located in the imaging hole 12a and the corner portion Sd is located in the imaging hole 12b. The support pedestal 12 is positioned to a substrate placing and extracting position which is lowered to a position separated from the mask 13 as indicated by a solid line in FIG. 3.

In the substrate imaging step S12 illustrated in FIG. 2, the substrate S placed on the support pedestal 12 of the ion implantation apparatus 10 is imaged with multiple digital cameras (imaging unit) 16a and 16b. Specifically, the corner portion Sc located in the imaging hole 12a is imaged with one digital camera (imaging unit) 16a, and the corner portion Sd located in the imaging hole 12b is imaged with the other digital camera (imaging unit) 16b. In order to perform the imaging process, the support pedestal 12 is raised to an ion implanting position in the vicinity of the mask 13 before the imaging as indicated by a dotted line in FIG. 3.

In the center calculating step S13 illustrated in FIG. 2, as illustrated in FIG. 1, data of the images captured with the digital cameras 16a and 16b are processed, the external form (outline) of the substrate S is specified from the image data, and a substrate center position Ss is calculated as follows.

First, the images of two corner portions Sc and Sd located at the diagonal positions and imaged separately are synthesized on the basis of the position information of the digital cameras 16a and 16b.

Subsequently, in the synthesized image, two neighboring sides out of four sides of a rectangle are identified in two corner portions Sc and Sd located at the diagonal positions, and the identified side Sg and the identified side Sh in the vicinity of the corner portion Sc are recognized as straight lines. The straight lines are made to extend and the intersection thereof is obtained as a virtual vertex (vertex) Sm. Similarly, the identified side Sj and the identified side Sk in the vicinity of the corner portion Sd are recognized as straight lines. The straight lines are made to extend and the intersection thereof is obtained as a virtual vertex (vertex) Sn.

All the identified sides Sg, Sh, Sj, and Sk have only to have a length enabling calculating of the virtual vertexes Sm and Sn.

Subsequently, a straight line SL connecting the virtual vertexes Sm and Sn is calculated and the midpoint of the straight line SL is set as the substrate center position Ss. The straight line SL which is a diagonal line is considered to intersect all the four sides Sg, Sh, Sj, and Sk of the substrate S at 45°.

In the processing position adjusting step S34 illustrated in FIG. 2, it is determined whether the calculated substrate center position Ss departs from a predetermined processing center defined by the position of the mask 13, and the position of the support pedestal 12 is adjusted in the in-plane direction so as to match the substrate center position Ss with the processing center. Similarly, it is determined whether the diagonal line SL departs from a predetermined processing direction defined by the position of the mask 13, and the position of the support pedestal 12 is rotationally adjusted in the 8 direction so as to match the diagonal line SL with the processing direction.

The center alignment step S10 for the ion implanting step S20 is finished in this way.

The method of calculating the substrate center position Ss as the method of aligning the substrate S is not limited to the above-mentioned method, but may employ a known substrate aligning method.

After the center alignment step S10 is finished and the substrate S is set to a position at which ion implantation is possible, an ion implanting process is performed as the impurity implanting step S20 illustrated in FIG. 2.

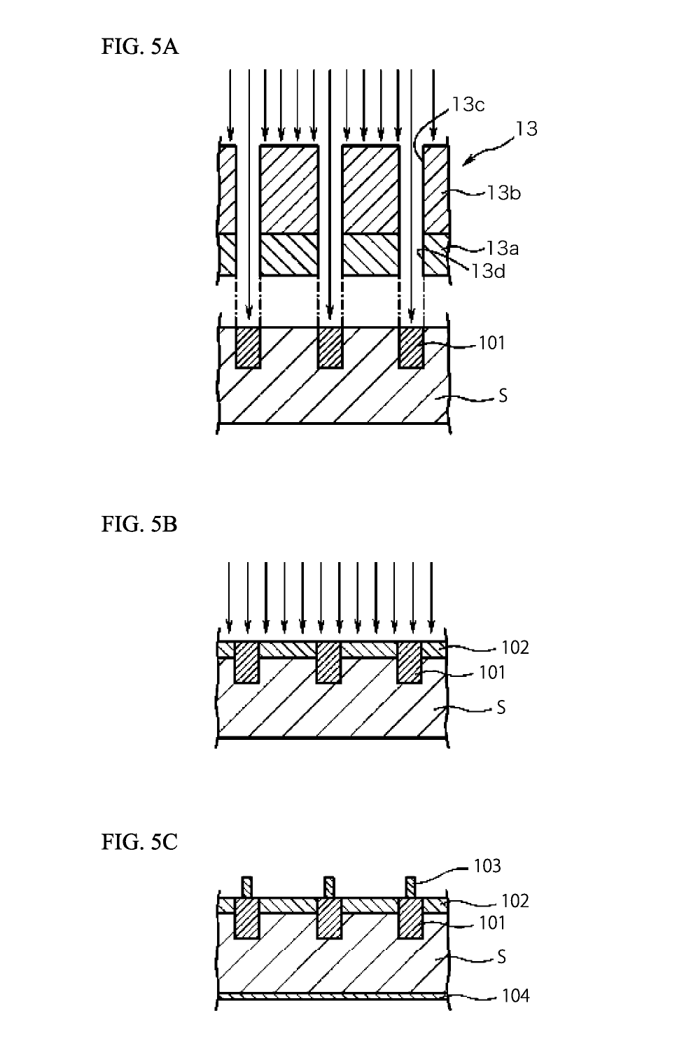

In the impurity implanting step S20, the processing chamber 11 is set to a processing atmosphere such as vacuum and introduction of phosphorus ions (ion irradiating process) via the mask 13 is performed on the substrate S. Here, when PH₃ (phosphine) including phosphorus is used as a gas to be introduced into a plasma source as an ion source, the ion irradiation conditions are set as follows. That is, a gas flow rate ranges from 0.1 to 20 sccm, AC power to be applied to an antenna ranges from 20 to 1000 W as high-frequency power with a frequency of 13.56 MHz, a voltage to be applied to the grid plate is 30 kV, and an irradiation time ranges from 0.1 to 3.0 sec. Accordingly, as illustrated in FIG. 5A, phosphorus ions are introduced into electrode forming areas of the substrate S via the apertures 13c and the through-holes 13d of the mask 13 to form the impurity regions (n⁺ layer) 101.

When the impurity regions (n⁺ layer) 101 are formed in the substrate S as described above, the mask 13 is moved to a retreating position to remove the mask 13 from between the substrate S located at the ion irradiation position and the grid plate of the ion irradiation source. Then, the entire surface of the substrate S is evenly irradiated with phosphorus ions. In this case, the voltage applied to the grid plate is changed to a range of 5 to 10 kV and the ion irradiation time is changed to a range of 0.1 to 3.0 sec. Accordingly, as illustrated in FIG. 5B, an n layer 102 is formed at a shallow position of the substrate S.

Subsequently, the substrate S is carried to an annealing furnace not illustrated and is subjected to an annealing process. In this case, for example, the annealing process is performed with the substrate temperature set to 900° C. and the processing time set to 2 minutes. Accordingly, defects generated in the substrate S due to the ion irradiation are repaired (that is, recrystallized).

The center alignment step S30 illustrated in FIG. 2 is a step of setting a substrate center position Ss as a reference position for processing of the electrode forming step S40 and includes the substrate placing step S31, the substrate imaging step S32, the center calculating step S33, and the processing position adjusting step S34.

In the substrate placing step S31 illustrated in FIG. 2, the substrate S is placed on the support pedestal 22 located at the alignment position indicated by a solid line on the left side of the drawing in the screen printing apparatus 20.

Subsequently, in the substrate imaging step S32 illustrated in FIG. 2, the entire substrate S placed on the support pedestal 22 located at the alignment position is imaged with the digital camera (imaging unit) 26. In order to perform the imaging process, since the support pedestal 22 retreats to the alignment position separated from the mask 23 before the imaging as indicated by a solid line in FIG. 6, the mask 23 does not interfere the imaging.

In the center calculating step S33 illustrated in FIG. 2, as illustrated in FIG. 1, data of the image captured with the digital camera 26 are processed, the external form (outline) of the substrate S is specified from the image data, and a substrate center position Ss is calculated as follows.

First, two neighboring sides out of four sides of a rectangle are identified in two corner portions Sc and Sd located at the diagonal positions from the image data of the entire substrate S captured with the digital camera 26, and the identified side Sg and the identified side Sh in the vicinity of the corner portion Sc are recognized as straight lines. The straight lines are made to extend and the intersection thereof is obtained as a virtual vertex (vertex) Sm. Similarly, the identified side Sj and the identified side Sk in the vicinity of the corner portion Sd are recognized as straight lines. The straight lines are made to extend and the intersection thereof is obtained as a virtual vertex (vertex) Sn. All the identified sides Sg, Sh, Sj, and Sk have only to have a length enabling calculating of the virtual vertexes Sm and Sn.

Subsequently, a straight line SL connecting the virtual vertexes Sm and Sn is calculated and the midpoint of the straight line SL is set as the substrate center position Ss. The straight line SL which is a diagonal line is considered to intersect all the four sides Sg, Sh, Sj, and Sk of the substrate S at 45°.

In the processing position adjusting step S34 illustrated in FIG. 2, it is determined whether the calculated substrate center position Ss departs from a predetermined processing center defined by the position of the mask 23, and the position of the support pedestal 22 is adjusted in the in-plane direction so as to match the substrate center position Ss with the processing center. Similarly, it is determined whether the diagonal line SL departs from a predetermined processing direction defined by the position of the mask 23, and the position of the support pedestal 22 is rotationally adjusted in the 8 direction so as to match the diagonal line SL with the processing direction.

The center alignment step S30 for the electrode forming step S40 is finished in this way.

The method of calculating the substrate center position Ss as the method of aligning the substrate S is not limited to the above-mentioned method, but may employ a known substrate aligning method.

In the electrode forming step S40 illustrated in FIG. 2, front electrodes 103 formed of Ag are formed on the substrate S, which has been subjected to the ion implanting process, using a known screen printing method.

In this step, as illustrated in FIG. 6, the support pedestal 22 having the substrate S placed thereon is moved from the alignment position (solid line) to the printing position (dotted line) by a support pedestal drive unit not illustrated, and the front electrodes 103 formed of Ag or the like are formed in the pattern defined by the screen 23.

In the post-processing step S50 illustrated in FIG. 2, a rear electrode 104 formed of Al or the like is formed on the rear surface Sb of the substrate S, whereby a solar cell having the selective emitter structure illustrated in FIG. 5C is obtained.

The post-processing step S50 includes all the processes necessary after forming the electrodes.

In this embodiment, since the processing positions are set by calculating the substrate center position Ss through the use of the center alignment step S10 and the center alignment step S30 before the processing of the impurity implanting step S20 and the electrode forming step S40, it is possible to accurately control the positions for forming the impurity regions 101 and the electrodes 103. Accordingly, even when an error occurs in the external form of the substrate S, it is possible to form the electrodes 103 so as not to protrude from the impurity regions 101 without being affected by the error. In addition, it is possible to accurately form the electrodes 103 with substantially the same width as the impurity regions having a width of about 50 to 500 μm, strictly, with a width smaller by about 10 μm or less than the width of the impurity regions 101. Accordingly, it is possible to manufacture a solar cell to correspond to substrates S having different dimensional specifications without causing a decrease in conversion efficiency.

In the center alignment step S10 according to this embodiment, the substrate center position Ss is calculated from image data obtained by imaging the external form (outline) of the substrate S through the use of the imaging units 16a and 16b located on the rear surface Sb side opposite to the processing surface Sa of the substrate S. Accordingly, since only the corner portions Sc and Sd of the substrate S can be imaged to set the substrate center position Ss in a state where the substrate S is located close to the mask 13 used for the impurity implantation, it is possible to accurately calculate the position of the substrate S. As a result, it is possible to accurately determine the processing position and to accurately perform the impurity implanting process on the entire surface of the substrate S.

In the center alignment step S30 according to this embodiment, the substrate center position Ss is calculated from an image acquired by imaging the external form (outline) of the substrate S by the use of the imaging unit 26 located on the front surface Sa side of the substrate S, whereby the substrate center position is obtained. Thereafter, the substrate S is moved by a predetermined amount (distance, direction, angle, or the like) in a direction parallel to the screen 23, that is, in the in-plane direction parallel to the front surface Sa of the substrate S, relative to the screen 23 used to form the electrodes. Accordingly, since it is possible to accurately determine the formation positions of the electrodes, it is possible to accurately form the electrodes 103 with substantially the same width as the impurity regions 101 having a width of about 50 to 500 μm, strictly, with a width smaller by about 10 μm than the width of the impurity regions 101.

In this way, in the center alignment step S10 and the center alignment step S30 according to this embodiment, since the alignment is carried out on the basis of the same substrate center position Ss, the impurity-implanted positions and the electrode-formed positions can be easily aligned with each other within 100 μm. In addition, since it is not necessary to form an alignment mark on the substrate, it is not necessary to perform the manufacturing steps corresponding thereto and the manufacturing cost is not increased.

In the solar cell manufacturing method according to this embodiment, two virtual vertexes are calculated, but four vertexes Sc, Sd, Se, and Sf may be calculated. In this case, it is possible to further improve alignment accuracy. At this time, it is possible to calculate the substrate center position Ss from the other diagonal line intersecting the straight line SL as a diagonal line. Multiple midpoints are calculated from the four vertexes and the substrate center position Ss can be calculated from the midpoints.

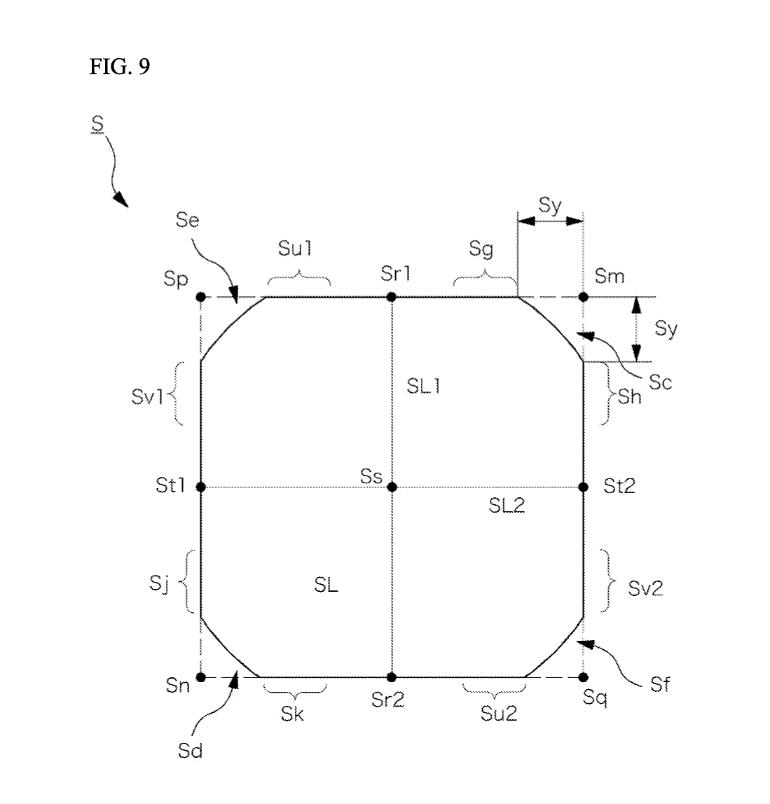

In the latter, in the center calculating step S13, as illustrated in FIG. 9, data of the images captured with the digital cameras 16a and 16b are processed, the external form (outline) of the substrate S is specified from the image data, and then a substrate center position Ss can be calculated as follows.

First, the images of two corner portions Sc and Se located adjacent to each other and imaged separately are synthesized on the basis of the position information of the digital cameras 16a and 16b.

Subsequently, in the synthesized image of the two corner portions Sc and Se, two neighboring sides out of four sides of a rectangle are identified. The identified side Sg and the identified side Sh in the vicinity of the corner portion Sc are recognized as straight lines. The straight lines are made to extend and the intersection thereof is obtained as a virtual vertex (vertex) Sm. Similarly, the identified side Su1 and the identified side Sv1 in the vicinity of the corner portion Se are recognized as straight lines. The straight lines are made to extend and the intersection thereof is obtained as a virtual vertex (vertex) Sp.

Similarly, in the other two vertexes, the identified side Sj and the identified side Sk in the vicinity of the corner portion Sd are recognized as straight lines. The straight lines are made to extend and the intersection thereof is obtained as a virtual vertex (vertex) Sn. Simultaneously, the identified side Su2 and the identified side Sv2 in the vicinity of the corner portion Sf are recognized as straight lines. The straight lines are made to extend and the intersection thereof is obtained as a virtual vertex (vertex) Sq.

Subsequently, a midpoint Sr1 of the straight line connecting the virtual vertexes Sm and Sp is calculated and a midpoint Sr2 of the straight line connecting the virtual vertexes Sq and Sn is calculated. A midpoint of a straight line SL1 connecting the midpoints Sr1 and Sr2 of the two opposite sides is set as the substrate center position Ss.

All the identified sides Sg, Sh, Sj, Sk, Su1, Sv1, Su2, and Sv2 have only to have a length enabling calculating of the virtual vertexes Sm, Sn, Sp, and Sq.

The straight line SL1 as a diagonal line is considered to form an angle of 90° about, that is, to be perpendicular to, any of two sides Sg (Su1) and Sk (Su2) of the substrate S.

Midpoints St1 and St2 corresponding to the other two sides from the four vertexes may be calculated and a midpoint of a straight line SL2 connecting the midpoints St1 and St2 may be set as the substrate center position Ss.

An intersection of the straight line SL1 connecting the midpoints Sr1 and Sr2 of the two opposite sides and the straight line SL2 connecting the midpoints St1 and St2 may be set as the substrate center position Ss.

The solar cell manufacturing method according to this embodiment is applied to manufacture a solar cell 100 in which impurities are implanted into the front surface Sa of the substrate S to form the n+ layer 101, the front electrodes 103 are formed thereon, and the rear electrode 104 is formed on the almost entire surface of the rear surface Sb thereof, but may be applied to manufacture a back-contact solar cell.

Specifically, as illustrated in FIG. 8, a solar cell 80 is a so-called back-contact solar cell in which electrodes 82 connected to an outside are formed on a rear surface 81b of a silicon substrate 81 having a rectangular plate shape as a semiconductor substrate.

More specifically, as illustrated in FIG. 8, in the silicon substrate 81 of the solar cell 80, an uneven texture is formed on a solar-light-receiving surface 81a and the rear surface 81b opposite to the light-receiving surface 81a. This silicon substrate 81 may be any one of a substrate formed of monocrystalline silicon and a substrate formed of polycrystalline silicon.

In the rear surface 81b of the silicon substrate 81, a P-type impurity region 81p and an N-type impurity region 81n which are regions in which impurity elements are diffused are alternately formed by a predetermined depth in the thickness direction of the silicon substrate 81 from the rear surface 81b. The P-type impurity region 81p includes elements such as boron (B), antimony (Sb), and bismuth (Bi) which are a first conductivity type of impurity elements. On the other hand, the N-type impurity region 81n includes elements such as phosphorus (P) and arsenic (As) which are a second conductivity type of impurity elements. An electrode 82 formed of aluminum, silver, or the like is formed in the P-type impurity region 81p and the N-type impurity region 81n so as to protrude from the rear surface 81b of the silicon substrate 81. In the P-type impurity region 81p and the N-type impurity region 81n, light incident on the light-receiving surface 81a of the silicon substrate 81 is converted into electric power. This electric power is extracted from the electrodes 82 connected to the impurity regions 81p and 81n to an external load or a power storage device.

The entire surface of the silicon substrate 81 is covered with a silicon oxide film 83 and a silicon nitride film 84 covering the silicon oxide film 83 so as to expose at least part of a protruding surface 82a of each electrode 82. The light-receiving surface 81a side of the silicon nitride film 84 has a thickness larger than that of the rear surface 81b side and serves as a reflection suppressing portion 84a suppressing reflection of light on the light-receiving surface 81a side. Light applied to the front surface of the solar cell 80 easily enters the silicon substrate 81 by the reflection suppressing function of the reflection suppressing portion 84a. The light entering the silicon substrate 81 is easily trapped by the texture formed on the light-receiving surface 81a and the rear surface 81b. Light entering the silicon substrate 81 or light trapped by the silicon substrate is converted into electric power through a photoelectric conversion operation in the P-type impurity regions 81p and the N-type impurity regions 81n. A passivation film that suppresses intrusion of impurities such as moisture into the silicon substrate 81, mechanical damage on the outer surface of the silicon substrate 81, and the like is formed by the silicon oxide film 83 and the silicon nitride film 84 including the reflection suppressing portion 84a.

In manufacturing the solar cell 80 having the above-mentioned structure, the substrate center position Ss can be calculated to correspond to the center alignment step S10 before a step of forming the P-type impurity regions 81p and the N-type impurity regions 81n, which corresponds to the impurity implanting step S20, and the substrate center position Ss can be calculated to correspond to the center alignment step S30 before the electrode forming step of forming the electrodes 82, which corresponds to the electrode forming step S40. Accordingly, it is possible to accurately set the formation positions of the electrodes and the impurity regions

The N-type impurity elements and the P-type impurity elements are implanted into the rear surface 81b of the silicon substrate 81 via the silicon oxide film 83 and the silicon nitride film 84. Accordingly, it is not necessary to separately form through-holes for diffusing the impurity elements in the silicon substrate 81 in the silicon oxide film 83 or the silicon nitride film 84. Accordingly, compared with the method of forming through-holes in the silicon oxide film 83 and the silicon nitride film 84, it is possible to reduce the number of steps for manufacturing the solar cell 80.

The silicon oxide film 83 and the silicon nitride film 84 are formed on the entire surface of the silicon substrate 81, and the thickness of the passivation film is made to be relatively small by making the thickness of the silicon nitride film relatively small on the rear surface 81b into which the impurity elements are implanted. Accordingly, it is possible to lower an acceleration voltage required for implantation of the impurity elements and to satisfactorily exhibit the function of the passivation film on the light-receiving surface 81a of the silicon substrate 81.

The thickness of the passivation film is made to be relatively small on the rear surface 81b by stacking silicon nitride on only the light-receiving surface 81a side after forming the silicon oxide film 83 and the silicon nitride film 84 on the entire outer surface of the silicon substrate 81. Here, in order to form through-holes for diffusing the impurities in the passivation film, at least two steps such as a step of forming a mask for suppressing a decrease in thickness of the region other than the through-holes and a step of forming the through-holes in the passivation film are necessary. On the contrary, even when the above-mentioned method in which the step of forming the passivation film includes forming the reflection suppressing portion 84a is used, only the step of forming the passivation film is added. Accordingly, even in the above-mentioned method, it is possible to reduce the number of manufacturing steps, compared with the method of forming through-holes in the passivation film.

The sum of the thickness of the silicon oxide film 83 and the thickness of the silicon nitride film 84 formed on the rear surface 81b is set to 30 nm. Accordingly, it is possible to more satisfactorily implant impurity elements into the silicon substrate 81 via the silicon oxide film 83 and the silicon nitride film 84.

The above-mentioned embodiment may be appropriately modified as follows. The thickness of the passivation film on the rear surface 81b side, that is, the sum of the thickness of the silicon oxide film 83 and the thickness of the silicon nitride film 84, is set to 30 nm. The thickness of the passivation film on the rear surface 81b side is not limited to this value, but may be preferably set to a range of 5 to 50 nm.

The thickness of the passivation film on the rear surface 81b is more preferably set to a range of 5 to 20 nm. When the thickness of the passivation film on the rear surface 81b is in this range, at least minimum mechanical and chemical protection can be made to the rear surface 81b, that is, it is possible to protect the rear surface 81b so as to satisfactorily maintain the conversion efficiency of the solar cell 80. In addition, since the thickness of the passivation film subjected to ion implantation with an ion beam can be made relatively small in the preferable thickness range, the amount of ions implanted into the silicon substrate 81 can be relatively increased. Accordingly, since a sufficient amount of ions implanted can be guaranteed with a relatively-short ion implantation time, it is possible to shorten a tack time required for manufacturing the solar cell 80.

When the thickness of the passivation film is set to be larger than 20 nm, it is possible to sufficiently mechanically and chemically protect the rear surface 81b. In addition, when the thickness of the passivation film is set to be equal to or less than 50 nm, damage to the silicon substrate 81 due to the irradiation with an ion beam can be more sufficiently prevented from increasing to such an extent to affect the conversion efficiency of the solar cell 80.

Compound semiconductor substrates such as gallium arsenide (GaAs) substrate, a cadmium sulfide (CdS) substrate, a cadmium telluride (CdTe) substrate, and a copper indium selenide (CuInSe) substrate or organic semiconductor substrates may be used instead of the silicon substrate 81.

In the above-mentioned embodiment, the N-type impurity regions 81n and the P-type impurity regions 81p are formed after the silicon oxide film 83 and the silicon nitride film 84 are formed on the entire surface of the silicon substrate 81. However, the present invention is not limited to this configuration, but the silicon oxide film 83 as a passivation film may be first formed, the impurity regions 81n and 81p may be formed thereon, and then the silicon nitride film 84 may be formed as another passivation film.

### DESCRIPTION OF THE REFERENCE SYMBOLS

100, 80: solar cell

S, 81: silicon substrate

Sa, 81a: light-receiving surface

Sb, 81b: rear surface

101: impurity region

81p: P-type impurity region (impurity region)

81n: N-type impurity region (impurity region)

82, 103, 104: electrode

83: silicon oxide film

84: silicon nitride film

84a: reflection suppressing portion

13: mask

23: screen (mask)

16, 26: digital camera (imaging unit)

Ss: substrate center position

1. A method of manufacturing a solar cell having an impurity region formed in a substantially-rectangular silicon substrate and an electrode formed to overlap with the impurity region, the method comprising:
an impurity implanting step of forming the impurity region;
an electrode forming step of forming the electrode;
a first center alignment step of setting a center position of the substrate as a reference position for processing the impurity implanting step; and
a second center alignment step of setting a center position of the substrate as a reference position for processing the electrode forming step.

2. The method of manufacturing a solar cell according to claim 1, wherein the first center alignment step includes calculating a substrate center position from an image acquired by imaging an external form of the substrate with an imaging unit located on the opposite side of a processing surface of the substrate.

3. The method of manufacturing a solar cell according to claim 1, wherein the second center alignment step includes calculating a substrate center position from an image acquired by imaging an external form of the substrate with an imaging unit located on the side of a processing surface of the substrate.

4. The method of manufacturing a solar cell according to claim 2, wherein the impurity implanting step includes implanting impurities using an ion implantation method.

5. The method of manufacturing a solar cell according to claim 3, wherein the electrode forming step includes forming the electrode using a printing method.

6. The method of manufacturing a solar cell according to claim 1, wherein the first or second center alignment step includes calculating a vertex by extending predetermined parts of two neighboring sides of the external form of the substrate, similarly calculating a vertex at a diagonal position thereof, and setting a midpoint of a diagonal line which is a straight line connecting the two vertexes as the substrate center position.

7. The method of manufacturing a solar cell according to claim 1, wherein the first or second center alignment step includes calculating a vertex by extending predetermined parts of two neighboring sides of the external form of the substrate, similarly calculating a vertex neighboring the vertex, determining a midpoint of a line connecting the two neighboring vertexes, calculating midpoints of opposite sides from the other two vertexes so as to correspond to the midpoint, similarly calculating midpoints of the other two opposite sides, and setting an intersection of straight lines connecting two points which are the midpoints of the two opposite sides as the substrate center position.

8. The method of manufacturing a solar cell according to claim 6, wherein the first or second center alignment step includes considering that an intersection angle of two neighboring sides of the external form of the substrate and the diagonal line is 45°.

9. The method of manufacturing a solar cell according to claim 8, wherein the first center alignment step includes imaging the external form of the substrate via an imaging hole penetrating a support pedestal on which the substrate is placed.

10. A solar cell manufactured using the method according to claim 1.
